(19) United States
(12) Patent Application Publication
(10) Pub. No.: US 2005/0018408 A1
(43) Pub. Date: Jan. 27, 2005

(54) Multiple mounting, self aligning, electronics enclosure (multimount)

(76) Inventor: David Aaron Rivkin, San Jose, CA (US)

Correspondence Address: David A. Rivkin, 1390 Curtis Avenue, San Jose, CA, 95125, US

(21) Appl. No.: 10/627,210

(22) Filed: Jul. 24, 2003

(51) Int. Cl. H05K 5/04; H05K 5/00; H05K 5/06

(52) U.S. Cl. 361/752

(57) ABSTRACT

An apparatus has been invented for the enclosure of electronic devices, electronics, electronic circuits and other materials, which provides for the apparatus to be supported or attached to a plurality of surfaces such as desktops, bulkheads, walls, panels, connectors, racks, structures and appendages. Such an apparatus also allows for the alignment and orientation of such enclosures to each other and other surfaces, allowing for multiple units to be manipulated as one assembly. The apparatus is also ergonomically correct for human hands in size, shape, texture and contour.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

1. Field of Invention

This invention relates to the enclosure or containment of industrial electronics, circuits and circuit boards, or other materials, specifically to the support of or attachment of such enclosures to various surfaces, desktops, backplanes, panels, walls, connectors, racks, structures or appendages, and to the alignment of such enclosures to each other and related articles.

2. Prior Art

While electronic enclosures are a mature product, many un-addressed or new problems with the existing designs remain. The industry has been unable to design one product to work for many surfaces, desktops, backplanes, panels, walls, connectors, racks, structures and appendages. New guidelines and legislation for ergonomic design of products to reduce worker stress have not yet been addressed by the industry. Because of these issues, assisting multiple enclosures to be aligned for ease of assembly has not been addressed. All of these issues have been addresses in this one invention presented here.

The industrial and electronics enclosures industry has numerous firms designing and manufacturing such enclosures for the marketplace. In this industry, standard terms have evolved which describe the different types of enclosures, relating to how they are used and attached to the surfaces to which they must be applied. Terms such as “Desktop Enclosure”, “Flanged Enclosure”, “Rack Mount Enclosure”, “Tube Enclosure”, “DIN Enclosure” and even the differentiation of “industrial Enclosure” vs. “Electronics Enclosure” have evolved to draw the clear distinction between the different ways of operating these distinct designs.

The Lego Brand block (FIG. 1a), U.S. Pat. 6,554,676, operates in a fashion that is useful for stacking and alignment of toy blocks (FIG. 1b).

[image]

### DISADVANTAGES OF PRIOR ART

Current electronic enclosures, mentioned above, require the user to redesign the electronics, circuits, circuit boards or other materials contained in these enclosures for each different mounting category. This would significantly increase the cost of design and manufacture of electronics, circuits, circuit boards and other components. Examples are leading firms such as Altech Corps' “Industrial”, “DIN” and “Electronics” enclosures (see Attachment A), Zimm Manufacturing‘s’ “Desk Top”, “Flanged”, “Rack Mount”, “Split Body”, “Formed Metal” and “Tube” (see Attachment B), and Fiboxs' “Cardmaster”, “Cardmaster 19” and “CardmasterII” (see Attachment C) enclosures. Recent concerns about the health and safety of workers, particularly with regard to repetitive stress injuries, have lead to new legislation and regulation in the US and abroad. General concerns for ergonomic design have increased. However, the designs of electronics enclosures have not responded to these concerns and are often not designed to fit in ones hand for even short periods of time, let alone long durations. This limitation in design is evident by the sharp, square edges on the products, the improper scale and size of the units, and the lack of gripable textures.

Current electronic enclosures do not take stacking or bundling into consideration. A typical “Desktop Enclosure” may have a flat surface onto which one could place another “Desktop Enclosure”, but this would not be stable and could easily fall off. DIN enclosures are placed on a DIN rail but they are installed one at a time onto the DIN rail, When building an entire factory full of tens of thousands of “DIN Enclosures”, this can lead to significant repetitive stress disorders. Flanged Enclosures are unable to be stacked and placed on top of one another and attached to a bulkhead or wall. “Tube Enclosures” are impossible to stack and connect even with screws without one or more rolling away. “Rack Mount Enclosures” can be stacked but aligning them so that they may be screwed together and to the rack may require multiple people to hold everything in alignment.

The Lego requires a great deal of force to engage the alignment, which does not allow for self-alignment with the assistance of gravity or minimal effort. The Lego is not an ideal design for the function of an electronic enclosure due to this behavior, as U.S. Pat. No. 6,554,676 clearly states, the intention is to have a specified amount of friction and force for the desired behavior.

### OBJECTS AND ADVANTAGES

Accordingly, several objects and advantages of my invention are:

To provide an enclosure which can be supported by or attached to various surfaces, desktops, backplanes, walls, panels, connectors, racks, structures or appendages
a) To provide an enclosure which is ergonomically correct
b) To provide an enclosure which requires little if any effort to align, stack, bundle or group and manipulate as one
c) To provide an enclosure which will remain in position when stacked, bundled or grouped
d) To provide an enclosure which can be manipulated into many positions for optimal use by the user
e) To provide enclosures which can be oriented the same for with ease for consistent stacking and accessibility
f) To provide an enclosure which can be used for numerous applications, alleviating the need for redesign of the enclosed components

Further objects and advantages of my invention will become apparent from a consideration of the drawings and ensuing description.

### BRIEF SUMMARY OF THE INVENTION

An invention has been developed for the enclosure or containment of electronics, circuits, and circuit boards or other materials, with a unique allowing for universal attachment to various surfaces, desktops, backplanes, walls, panels connectors, racks, structures or appendages, and to the alignment of such enclosures to each other and related articles.

### BRIEF DESCRIPTION OF THE SEVERAL VIEWS OF THE DRAWINGS

Drawing Figures

FIG. 2a—Front/Left Side view of enclosure

FIG. 2b—Front/Right Side view of enclosure

FIG. 2c—Front/Bottom view of enclosure

FIG. 2d—Back/Side view of enclosure

FIG. 3a—Close-up of eyelets for screw (Top/Back)

FIG. 3b—Close-up of eyelets for screw (Bottom/Front)

FIG. 3c—Close-up of DIN rail connection

FIG. 4a—Example Alignment Objects using inset showing mating surfaces

FIG. 4b—Example Alignment Objects using logo showing mating surfaces

FIG. 5a—Stacking of enclosures (Horizontal)

FIG. 5b—Grouping of enclosures (Vertical)

FIG. 5c—Stacking of enclosures (Perspective View)

FIG. 6a—Enclosure placed on desktop, in rack or on other horizontal surface on its side

FIG. 6b—Enclosure placed on desktop, in rack or on other horizontal surface on its bottom

FIG. 6c—Enclosure placed on desktop, in rack or on other horizontal surface on its back

FIG. 6d—Enclosure placed attached (with screws etc) to a bulkhead, wall, panel or other vertical surface

FIG. 6e—Enclosure supported by appendage (hand held)

FIG. 6f—Enclosure supported by DIN rail

FIG. 7—Enclosure surfaces showing ergonomic considerations

Reference Numerals in Drawings

1. Top face
2. Front face
3. Left face
4. Right face
5. Rear face
6. Bottom face
7. Top/Rear eyelet
8. Front/Bottom eyelet
9. Stabilizer
10. Top DIN rail engagement
11. DIN rail catch
12. DIN rail catch housing
13. Bottom DIN rail engagement
14. Assembly screw holes
15. Left Clamshell
16. Right Clamshell
17. Top Bezel
18. Front Bezel
19. Alignment element, male couplings surfaces
20. Alignment element, female couplings surfaces
21. Alignment element, male logo couplings surfaces
22. Alignment element, female logo couplings surfaces
23. Alignment elements mated
24. Enclosure in contact with horizontal surface, laying on side
25. Enclosure in contact with horizontal surface, standing
26. Enclosure in contact with horizontal surface, laying on back
27. Enclosure in contact with surface
28. DIN rail
29. Multiple enclosures combined to act as one
30. Proportions and scale of enclosure
31. Rounded edges
32. Textured surface
33. Human appendage (hand)

### DETAILED DESCRIPTION OF THE INVENTION

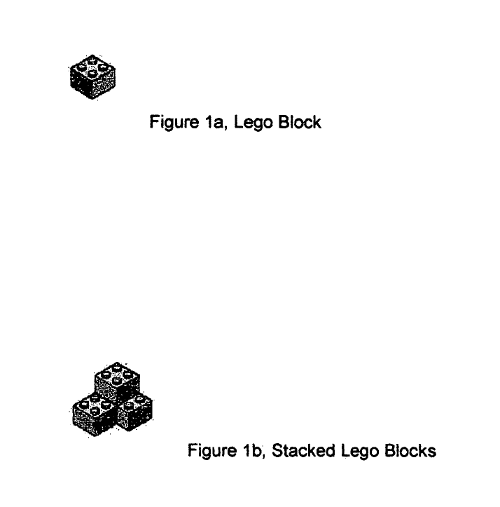

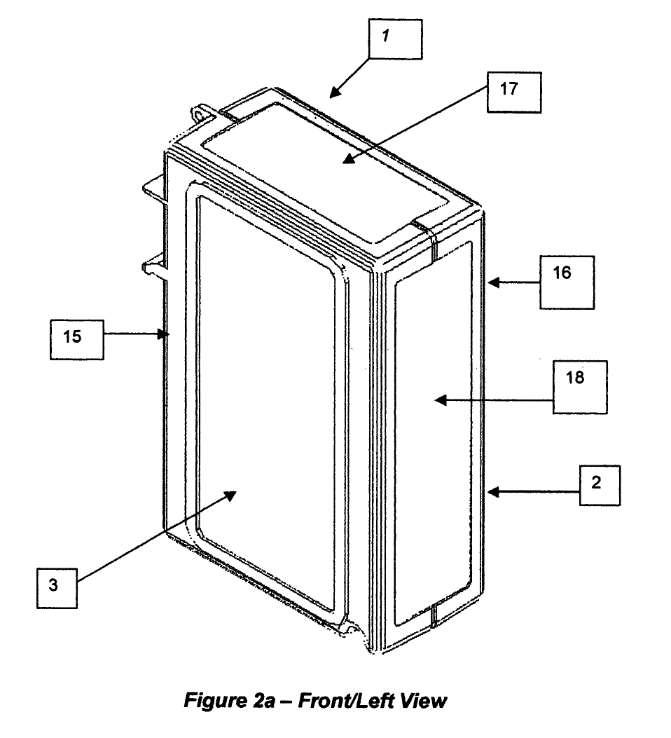

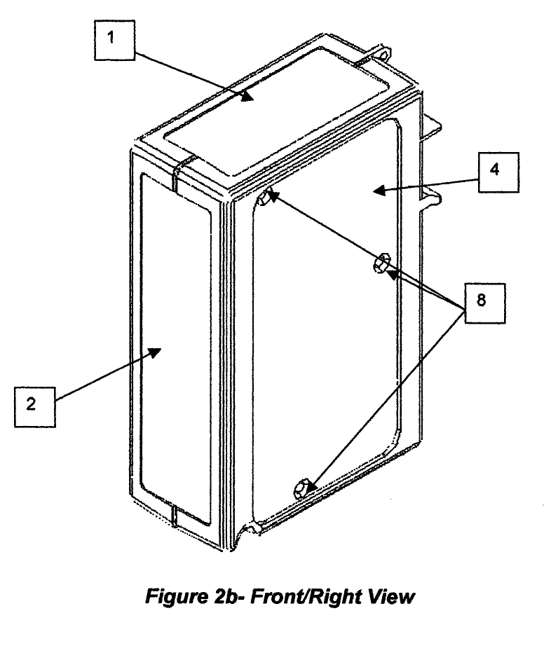

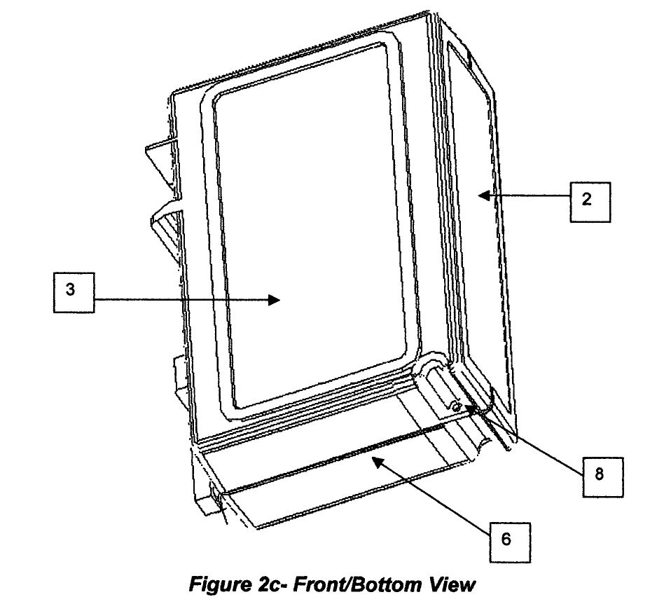

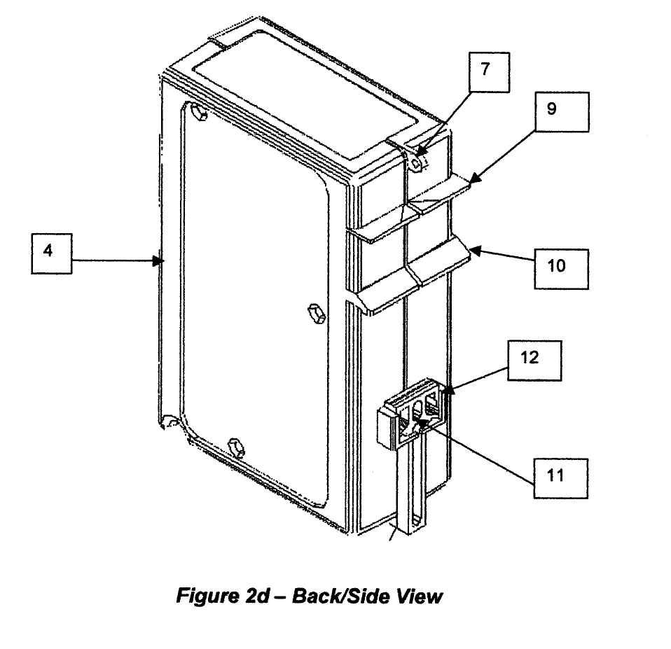

Description—FIGS. 2a to 2d

A typical embodiment of the present invention is illustrated in FIGS. 2a to 2d showing Front/Left Side, Front/Right Side, Front/Bottom, and Back/Side views. The enclosure may be made from plastic, metal, epoxy, silicone, paper, wood, glass, a composite of materials or any other solid or semisolid material. The enclosure may be manufactured in many ways including molding, machining, diecasting, carving, 3D lithography, or other solid or semisolid manufacturing technique.

The enclosure is roughly rectangular and proportioned to fit in the average human hand, roughly 1.25 inches wide by 4.25 inches tall and 2.75 inches deep. The enclosure can composed of 5 components, the left clamshell (15), the right clamshell (16), the top bezel (17), the front bezel (18) and the DIN rail catch (15). The top bezel (17) and front bezel (18) could also be integrated with one or more of the clamshells to reduce the total part count and ease assembly.

3 screws are used to hold the enclosure together and are inserted via the assembly screw holes (14). There are various possibilities with regard to the relative disposition of the sides, dimensions and screw hole count and location.

Near the top (1) and rear (5) and corner of the enclosure, is an eyelet (7) for insertion of a screw, rod, wire, string, rivet, or other fastener for attaching the enclosure to surroundings or to each other. This eyelet extends no further than the DIN rail engagement (10), and DIN rail catch housing (12) in order to allow the enclosure to stand on its back. Near front (2) and bottom (6) corner is another eyelet (8) for the same purpose. This eyelet is recessed into the bottom (6) of the enclosure in order to allow for standing the enclosure on its bottom. The DIN rail catch (11) is encompassed by the DIN rail catch housing (12) in such a way as to prevent it from being removed from an assembled enclosure. The DIN rail catch (11) is also symmetrical, allowing for error free assembly.

At the rear (5) of the enclosure, are the top DIN rail engagement (10), and the DIN rail catch (11) and its housing (12). These elements function together to provide snap-on contact with a DIN rail. Also on the rear is a stabilizer (9) which works with the DIN rail engagement (10) and DIN rail catch housing (12) when the enclosure is placed with its back (5) against a surface.

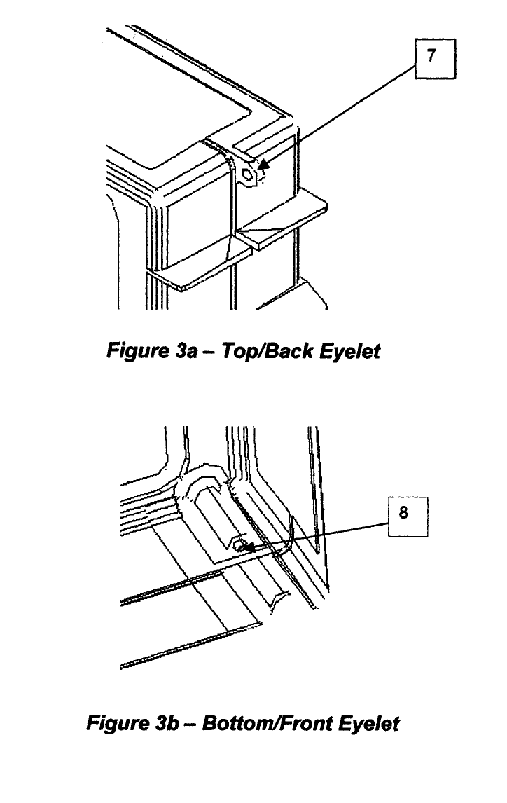

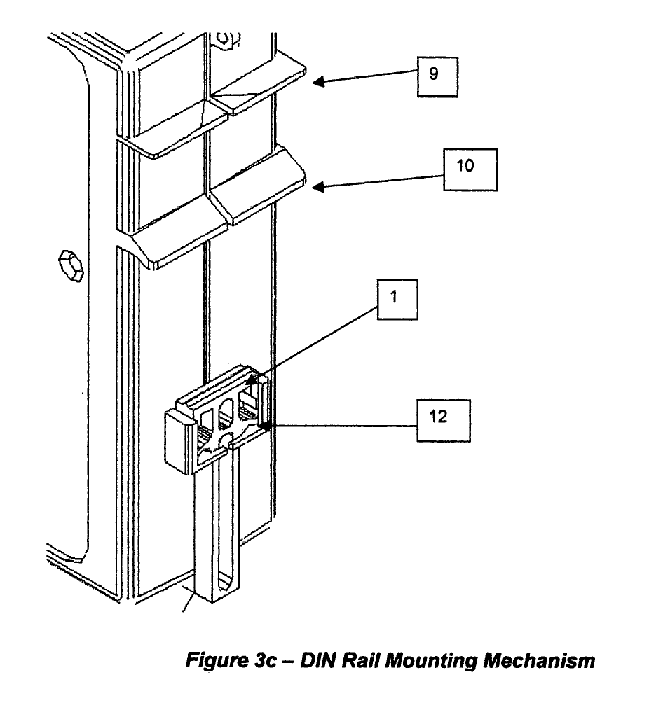

Description—FIGS. 3a to 3c

Close-up views of the elements of the enclosure are illustrated. The top/rear eyelet (7) located roughly near the top (1) and rear (5) corner is roughly centered across the rear (5). This allows for greater stability should a screw, rod, wire, string, rivet or other fastener be used to attach the enclosure to surfaces or other enclosures. The bottom/front eyelet (8) is also centered in the bottom (6) face for the same reason. This eyelet (8) is recessed into the bottom (6) of the enclosure in order to allow for standing the enclosure on its bottom. The DIN rail catch (11) is encompassed by the DIN rail catch housing (12) in such a way as to prevent it from being removed from an assembled enclosure.

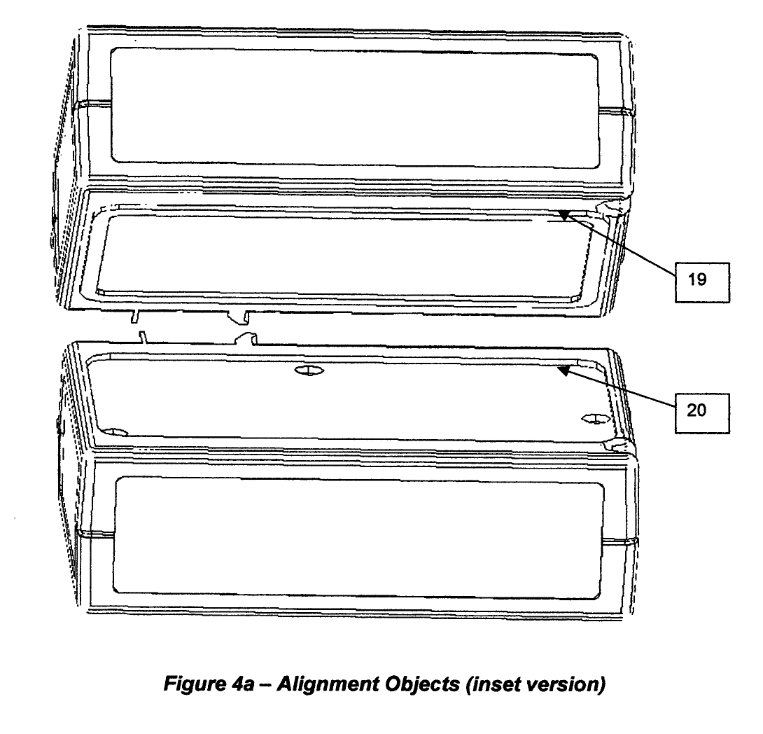

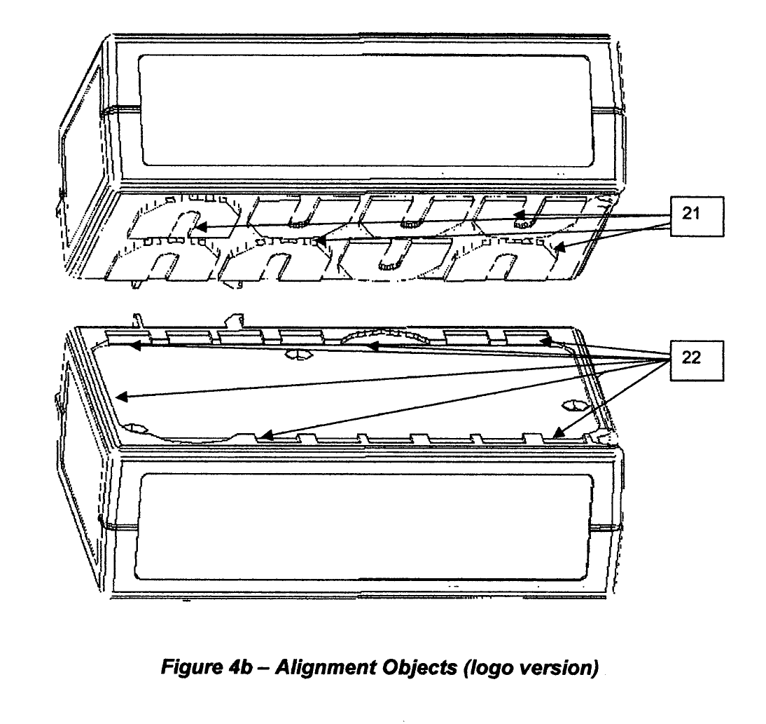

Description—FIGS. 4a and 4b

A typical embodiment of the present invention is illustrated in FIGS. 4a and 4b showing various possibilities for alignment elements. Male (19 & 21) and female (20 & 22) alignment elements provide mating surfaces which are roughly the same size and shape, differing by less than 0.005 inch which allows the coupling surfaces to glide past one another without significant friction, thereby allowing gravity to induce the alignment. The coupling surfaces are angled slightly, allowing for greater freedom when the enclosures are further apart, and less freedom when the enclosures are closer together. Use of non-symmetrical designs such as the male (21) and female (22) logo coupling surfaces, also allow for the consistent orientation of multiple enclosures.

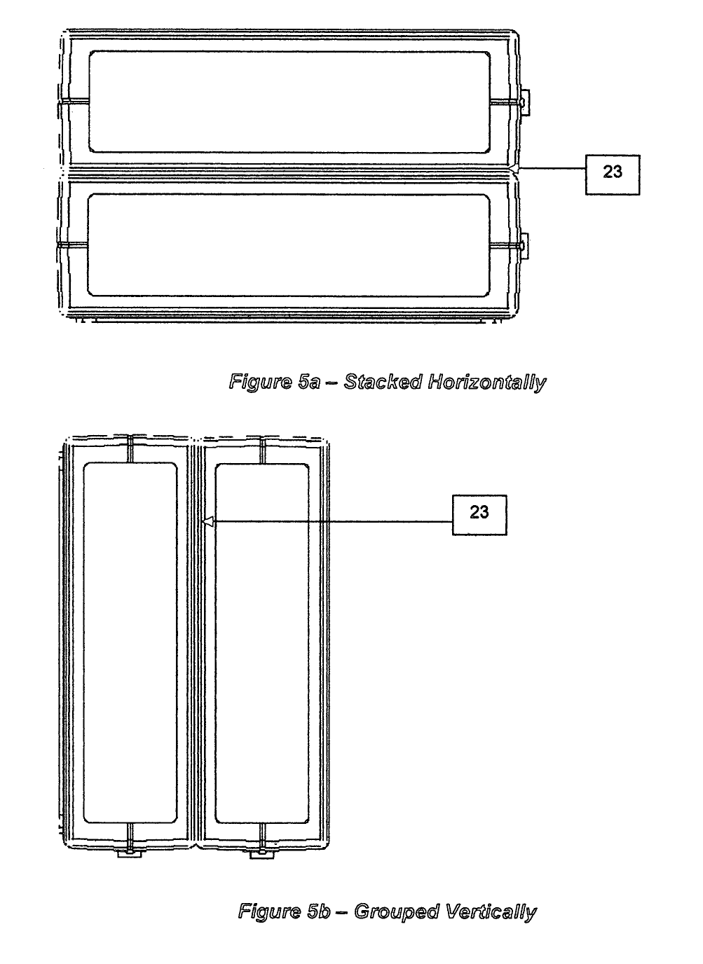

Operation—FIGS. 5a to 5c

The manner of using the invention to align to other enclosures is illustrated. The enclosures mate (23) by the left (3) and right (4) faces meeting along coupling surfaces (19, 20, 21 and 22). The result of such alignment of mated enclosures is an object that can be manipulated as if it were one object (29).

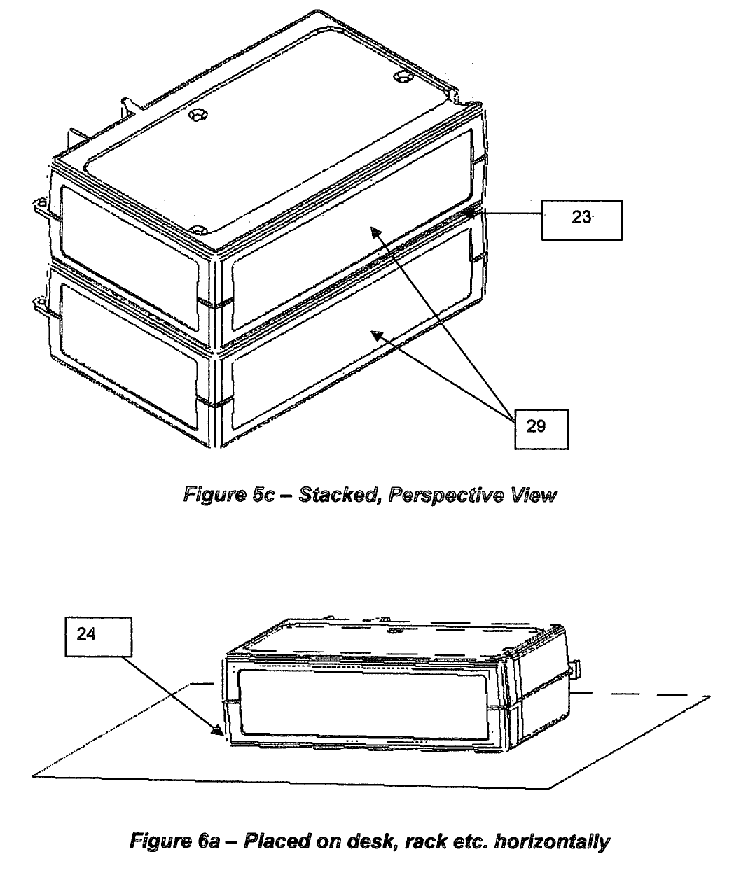

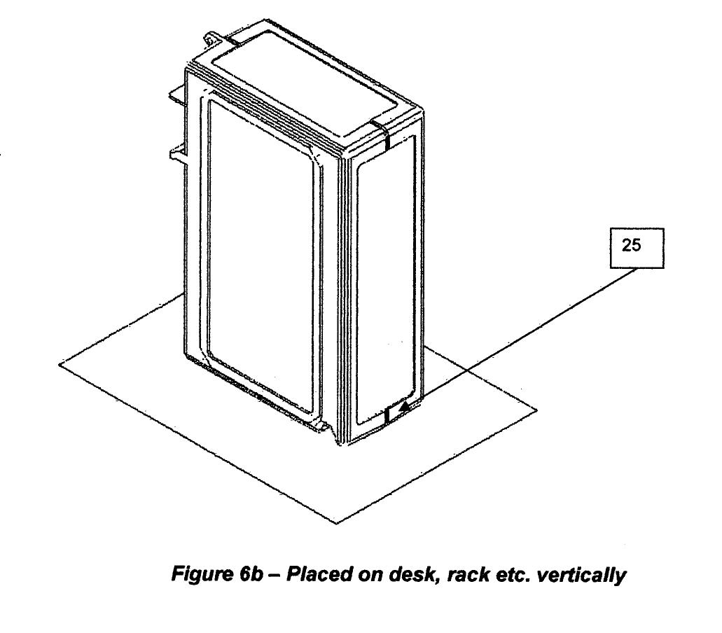

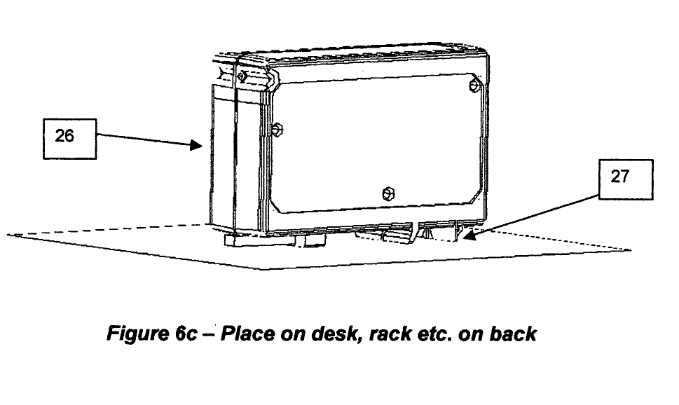

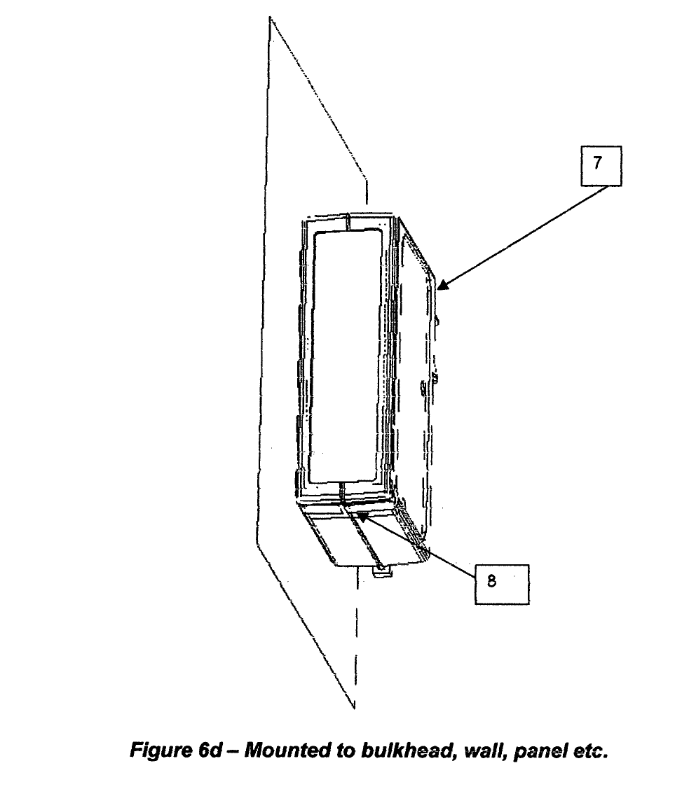

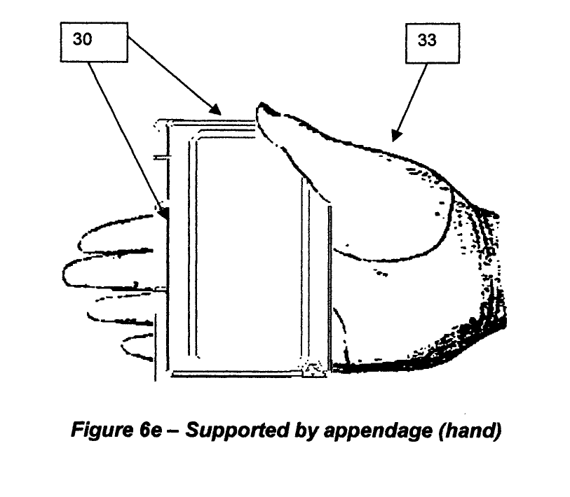

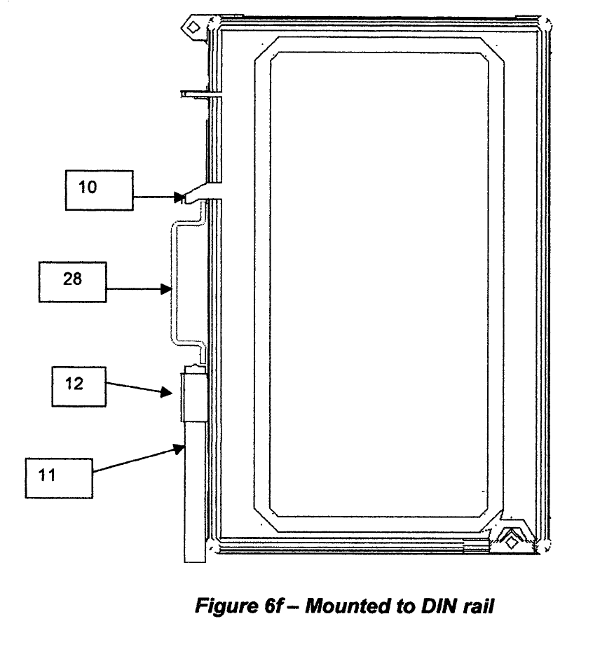

Operation—FIGS. 6a to 6f

The manners of using the invention to support or mount to other enclosures are illustrated. In each illustration, the enclosure is in contact with a surface (27) or connector such as the DIN rail (28) including the use of screw, rod, wire, string, rivet or other fastener.

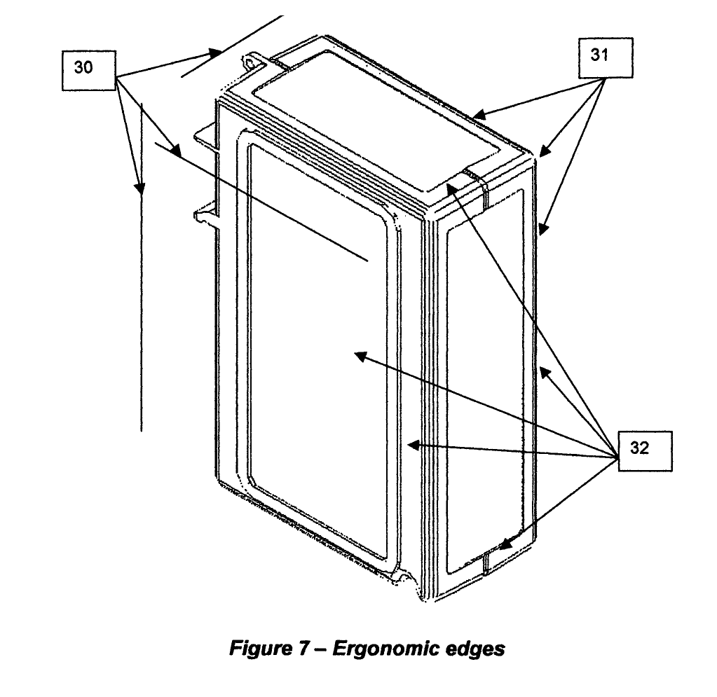

Description—FIGS. 6e and 7

A typical embodiment of the present invention shows the ergonomic considerations build into the design is illustrated. The proportions and scale (30) of the enclosure are ideal for the average human hand to hold comfortably for extended durations or to be held and released repeatedly as might be employed in an assembly line. The edges (31) are rounded with a roughly 1/8 inch radius of curvature to prevent any sharp edges causing pressure points or abrasions to a human hand. The surface us a slight texture (32) (Mold-Tech #11020) in order to provide better grip in the human hand.

Summary, Ramifications and Scope

Accordingly, the reader will see that this invention can be used to contains electronics, circuits, circuit boards and other components in a manner that allows for one design of such components can be supported or attached to a multitude of different objects. The invention has the advantages in that:
it permits the support or attachment of the enclosures to a multitude of surfaces
it permits the self-alignment of multiple enclosures with little or no force
it permits the enforced orientation of multiple enclosures
it permits the enclosure to be ergonomically correct

Although the description above contains many specifications, these should not be construed as limiting the scope of the invention but as merely providing illustrations of some of the presently preferred embodiments of this invention,

Thus the scope of the invention should be determined by the appended claims and their legal equivalents, rather than by the examples given.

[image]

[image]

[image]

[image]

[image]

[image]

[image]

[image]

1. An apparatus comprising an enclosure configured for receiving at least one electronic device, wherein the enclosure includes a plurality of elements providing a means of support or attachment.

2. The apparatus of claim 1 wherein at least one electronics device is encapsulated.

3. The apparatus of claim 1 wherein at least one electronics circuit is encapsulated.

4. The apparatus of claim 1 wherein at least one circuit board is encapsulated.

5. An apparatus comprising an enclosure with inter-connectible elements wherein each element means is capable of fitting within or mating with elements of the first enclosure element.

6. The apparatus of claim 5 wherein the inter-connectible elements require the orientation of the enclosure be maintained between adjacent enclosures.

7. An apparatus comprising an enclosure, wherein the enclosure includes ergonomic surfaces or textures.
